(19) United States
(12) Patent Application Publication
(10) Pub. No.: US 2026/0114618 A1
(43) Pub. Date: Apr. 30, 2026

(54) SEQUENTIALLY ACTUATED MATING MECHANISM (SAMM)

(71) Applicant: FCI USA LLC, Etters, PA (US)

(72) Inventors: James J. Muha, Boiling Springs, PA (US); Hans Bakermans, Boiling Springs, PA (US); Kevin Mejia-Saba, York, PA (US)

(73) Assignee: FCI USA LLC, Etters, PA (US)

(21) Appl. No.: 19/348,911

(22) Filed: Oct. 3, 2025

Related U.S. Application Data
(60) Provisional application No. 63/711,644, filed on Oct. 24, 2024.
(60) Provisional application No. 63/817,068, filed on Jun. 3, 2025.

(51) Int. Cl. A47B 88/457; H05K 7/14

(52) U.S. Cl. CPC A47B 88/457; H05K 7/1489; H05K 7/1492

(57) ABSTRACT

A connector assembly that can drive multiple connectors through a mating or unmating sequence in which the connectors move in unison for a first part of the sequence and move in a staggered fashion for a second part of the sequence. The second part of the sequence may include an interval of largest mating force for the connectors, such that the largest mating force for each connector occurs at different times. The maximum total mating force for all the connectors is therefore reduced relative to an assembly in which connectors move in unison over the entire sequence. The connector assembly may include a connector actuator component and a drive mechanism. The connector actuator component may be mounted along a side of an electronic tray inserted in a rack and may be coupled, permanently or separably, to a drive mechanism at an end for engaging connectors in a sideplane.

### CROSS-REFERENCE TO RELATED APPLICATIONS

This application claims priority to and the benefit under 35 U.S. C. § 119(e) of U.S. Provisional Patent Application Ser. No. 63/817,068, filed on Jun. 3, 2025, entitled “SEQUENTIALLY ACTUATED MATING MECHANISM (SAMM).” This application also claims priority to and the benefit under 35 U.S. C. § 119(e) of U.S. Provisional Patent Application Ser. No. 63/711,644, filed on Oct. 24, 2024, entitled “SEQUENTIALLY ACTUATED MATING MECHANISM (SAMM).” The contents of these applications are incorporated herein by reference in their entirety.

### TECHNICAL FIELD

The present disclosure generally relates to electronic systems, such as those assembled by inserting subassemblies into a rack.

### BACKGROUND OF THE INVENTION

Equipment racks are used to hold electronic assemblies that are interconnected into computer systems (e.g., network systems, server farms, data centers). The electronic assemblies, for example, may be servers, switches, graphics processing units (GPUs), network interface cards or other assemblies that operate together as part of a larger computer system. Each of these electronic assemblies may have a form factor that can be inserted into a slot within the rack. In some systems, the electronic assemblies are formed as printed circuit boards with components attached to them. In other systems, components interconnected by cables may be attached to a support structure, such as a tray, and the tray may be inserted into the slot as an electronic assembly.

A slot may be defined by rails that support an electronic assembly such that the height of the slot matches the distance separating the rails. However, there may not always be physical structures delimiting slots. Rather, a slot may be defined by mounting locations for an electronic assembly or connection points for electrical and fluid connections to an electronic assembly inserted in the slot. Regardless, the height of the slot limits the height of the electronic assembly that can be inserted into the slot. The slot height may be small to enable a large number of electronic assemblies to be installed in a rack to form a powerful computer system.

Regardless of the form of the electronic assemblies, the equipment rack may be configured to make connections to and among the inserted electronic assemblies. The equipment rack, for example, may be configured such that insertion of an electronic assembly fully into a slot in the rack makes connections to power sources at the back of a slot. As another example, connections for cooling fluid to flow from the rack to the electronic assembly and back may be completed by insertion of the electronic assembly into a slot.

Further a rack may also include infrastructure for making electrical connections among the electronic assemblies inserted into the rack. Conventionally, large printed circuit boards, known as backplanes, have been used to interconnect the electronic assemblies in racks. The backplanes form a plane at the back of a rack, opposite the plane in the front through which electronic assemblies are inserted into slots of the rack. Multiple electrical connectors are mounted to the backplane to align with the slots in the rack. Those connectors are interconnected via conductive traces within the backplane. With this arrangement, an electronic assembly can be pushed into a slot until connectors on the electronic assembly mate with connectors on the backplane.

More recently, electrical connections for carrying high speed signals between electronic assemblies inserted in a rack have been made through cable harnesses. The harnesses may be inside a mechanical structure, sometimes called a cable cartridge. The cable harnesses are terminated with connectors that are mounted to the cable cartridge such that the connectors, as with connectors on a PCB backplane, are aligned with the slots. In this way, connectors on the electronic assemblies may mate with corresponding connectors of one or more cable cartridges. When the cable cartridges are located at the back of the rack, the mating connectors may be forced into a mating position by the force of insertion of the electronic assembly into the rack. For a large system in which each electronic assembly may make thousands of connections, the force required to fully insert an electronic assembly such that the connectors mate with the backplane connectors may be generated by a user pushing on levers on the electronic assemblies that engage with the rack.

When the cable cartridge is mounted to a side of the rack (referred to herein as a “sideplane” configuration), high speed electrical connections between a tray and cable cartridge might be made after the tray is inserted into the rack. A user might push on a mechanical structure, for example, which applies a force on the connectors on the electronic assembly to push them towards the cable cartridges. Other connections, such as for power or cooling fluid, might nonetheless be made upon insertion of the electronic assembly into the rack.

### SUMMARY

Aspects of the present disclosure relate to a connector assembly configured to drive each of multiple connectors in accordance with a process that lowers mating and/or unmating force.

### BRIEF DESCRIPTION OF THE DRAWINGS

The accompanying drawings are not intended to be drawn to scale. In the drawings, each identical or nearly identical component that is illustrated in various figures may be represented by a like numeral. For purposes of clarity, not every component may be labeled in every drawing. In the drawings:

FIG. 1A is a front perspective view of an equipment rack with a cable backplane;

FIG. 1B is a front perspective view of a portion of an equipment rack with a cable sideplane;

FIG. 2 is a front, upper, right perspective view of portions of an equipment rack with cable sideplanes on a left and right side and a tray in the rack and electronic components in the tray, other than exemplary connector assemblies, omitted for clarity;

FIG. 3 is a front, lower, left perspective view of portions of an equipment rack with cable sideplanes on a left and right side and a tray in the rack and electronic components in the tray, other than exemplary connector assemblies, omitted for clarity;

FIG. 4 is a front, upper, left perspective view of portions of an equipment rack with cable sideplanes on a left and right side and a tray in the rack and electronic components in the tray, other than exemplary connector assemblies, omitted for clarity;

FIG. 5 is a perspective view of an exemplary connector assembly, with support members, such as a cover and/or substrate omitted for clarity;

FIG. 6A is a perspective view of the exemplary connector assembly of FIG. 5, with housings for the subassembly actuators omitted and a callout showing details of eccentric elements within a subassembly actuator;

FIG. 6B is a perspective view of the exemplary connector assembly of FIG. 6A, with additional housing elements omitted and a connector subassembly exploded to reveal exemplary eccentric elements of the connector subassembly;

FIG. 6C is a perspective view of the exemplary connector assembly of FIG. 6B, with eccentric elements of the connector subassembly hidden to reveal exemplary features of shaft 550 and a side of an adjacent connector subassembly;

FIG. 7 is a perspective view of a shaft and exemplary eccentric elements of a plurality connector subassemblies of a connector assembly, annotated to show staggered mounting of the eccentric elements to the shaft;

FIG. 8 is a perspective view of an exemplary assembly actuator in an extended state;

FIG. 9 is a perspective view of an exemplary subassembly actuator;

FIG. 10 is a top view of a connector assembly in three different stages of a mating sequence;

FIG. 11 is a flowchart of a method of assembling an electronic system with a connector assembly actuated by rotation of an engagement feature;

FIG. 12A is a perspective view of an exemplary embodiment of a connector assembly with a separable drive mechanism;

FIG. 12B is an alternative perspective view of the exemplary embodiment of the connector assembly of FIG. 12A;

FIG. 13 is a perspective view of the drive mechanism of FIG. 12A with a cover removed;

FIG. 14 is an alternative perspective view of the drive mechanism of FIG. 13, partially exploded.

### DETAILED DESCRIPTION

The inventors have recognized and appreciated designs for compact connector assemblies that facilitate reliable mating between high speed connectors of an electronic assembly, such as a tray, and connectors on a cable cartridge or backplane of a rack. The connector assembly may be compact, such that it fits within an envelope for an electronic assembly short enough to fit in a slot of a rack in dense computer system. Despite the limited height available for such a connector assembly, the connector assembly may move connectors of the assembly over a relatively large distance to ensure reliable engagement of the connectors to support high speed electrical connections. The inventors have also recognized benefits associated with moving connectors of the assembly into mating contact without employing biasing elements such as springs. For example, the inventors have recognized and appreciated designs for connector assemblies that facilitate mating of the connectors by actuating drive mechanisms.

In some examples, the connector assembly may move connectors in phases such that mating force is distributed over time. Distributed mating force, in turn may enable thinner materials to be used, further reducing the size and/or reducing the cost of the connector assembly. In one phase, multiple connectors in the connector assembly may be driven in unison. In this phase, the connectors of the connector assembly may be separated from mating connectors, but those connectors may be brought together for mating (or conversely separated for unmating). In another phase, the connectors of the connector assemblies may move in groups, with each group containing one or more connectors. This phase may include multiple sub-phases in which each group is driven separately into a fully mating position or separated from the fully mated position. In this way, the maximum mating force that the connector subassembly must overcome is the mating/unmating force for the group with the most connections. In some examples, the groups may be driven in a staggered fashion such that each group passes through its point of largest mating or unmating force at a different point in the mating or unmating process, yielding a lower peak mating or unmating force than if the groups of connectors were driven in unison.

In some examples, the connector assembly may be driven by a rotary motion, which might be applied by a user turning a handle or using a tool to rotate a shaft. Such a configuration, for example, may further limit the space needed for the connector assembly to be installed and operated, further facilitating its use in a dense computer system. Moreover, driving the connector assembly with a rotary motion may apply less torque relative to their mating axis on the connectors than other mechanisms of moving the connectors for mating and unmuting, which in turn may reduce the chances of binding of the system during mating or unmating of the high speed electrical connection.

As a specific example, a connector assembly as described herein may be mounted within a tray for mating connectors of the tray to connectors of a sideplane cartridge. Such a connector assembly may include two or more subassemblies, each of which supports one or more connectors. One or more assembly actuators may move all the subassemblies and their associated connectors in unison in a first phase of mating. In some examples, two assembly actuators may be positioned on opposite sides of a line of connector subassemblies, reducing twisting of the connectors about their mating axis when the connector assembly is driven.

Each subassembly may include at least one subassembly actuator. The subassembly actuators may be configured to move groups of one or more subassemblies sequentially in a second phase of the mating.

As a specific example, the assembly actuators and each of the subassembly actuators may each include one or more members mounted on a shaft such that rotation of the same shaft can both drive the assembly actuator to move the connector subassemblies as a group and drive the subassembly actuators to move the connector subassemblies individually. The members, for example, may operate as cams, such that rotation of the cam pushes a counter member fixed, directly or indirectly, to the connectors that are to be driven by the actuator. The assembly actuators and each of the subassembly actuators may be configured differently such that these cams or other members of the actuator engage their respective counter members over different ranges of angular motion of the shaft, creating phased motion of the connector assembly.

In the examples illustrated, the one or more members mounted to the shaft may be eccentric elements. In some examples, each actuator may have at least two eccentric elements, with one used to drive the connector assemblies toward an extended position for mating to connectors of a side cartridge and the other to drive the connector assemblies from the extended position toward a retracted position.

In some examples, the shaft may be slidably mounted within the connector assembly such that it can slide towards the extended position or towards the retracted position. The eccentric elements of the assembly actuators may be configured to drive the shaft toward the extended position when the shaft is rotated in one direction or toward the retracted position when the shaft is rotated in the opposite direction over a range of angular positions of the shaft.

The eccentric elements associated with each of the subassemblies may be shaped similarly to each other but mounted to the shaft with different angular orientations. Rotation of the shaft may drive each of the subassemblies when the eccentric element for that connector subassembly rotates into engagement with a support of the connector subassembly. The eccentric elements may be mounted such that the eccentric elements of the connector subassemblies of only one group of connector subassemblies engages their respective supports at different times, providing for motion of the groups of connector subassemblies individually.

This motion of the connector subassemblies is relative to the shaft. As the actuators of connector subassemblies are coupled to the same shaft as the assembly actuator, when the assembly actuator drives the shaft, the connector subassemblies move with the shaft.

In some examples, components of the connector assembly may be manufactured as an integrated assembly but in other examples, components may be separately manufactured and subsequently integrated, such as when they are attached to a tray. An assembly drive mechanism, for example, may be formed as part of an assembly with a support for connector subassemblies. In other examples, the assembly drive mechanism may be manufactured as a separate component from a connector actuation component containing the connector subassemblies and a supporting structure. In this configuration, the assembly drive mechanism optionally may be coupled to the connector actuation component for mating or unmating the connectors and then removed once the desired operation is completed. In this way, a single assembly drive mechanism may be shared across multiple connector assemblies.

Such an assembly and process of mating connectors supports secure connection between connectors on a tray and connectors of a sideplane cartridge. The mating process facilitated by the assembly may result in sequential mating of the connectors of each subassembly with corresponding mating connectors of the sideplane cartridge.

Optionally, the eccentric elements of the drive mechanisms of the actuator and each subassembly actuator may be cams. In some examples, a rack and pinion alternative or additionally may be used as the actuator for the connector assembly and/or the connector subassemblies. The two-phase mating process may be based on rotation of the shaft. The shaft may be rotated using an engagement feature. In some examples, the engagement feature may be a knob, which a user might grasp, or keyway, into which a user might insert a tool to provide rotation.

Features as described herein may be used alone or in any suitable combination. The features are described in connection with examples as provided in the figures. Turning to the figures, aspects of a connector assembly configured to mate connectors on a tray with connectors of a sideplane cartridge are illustrated.

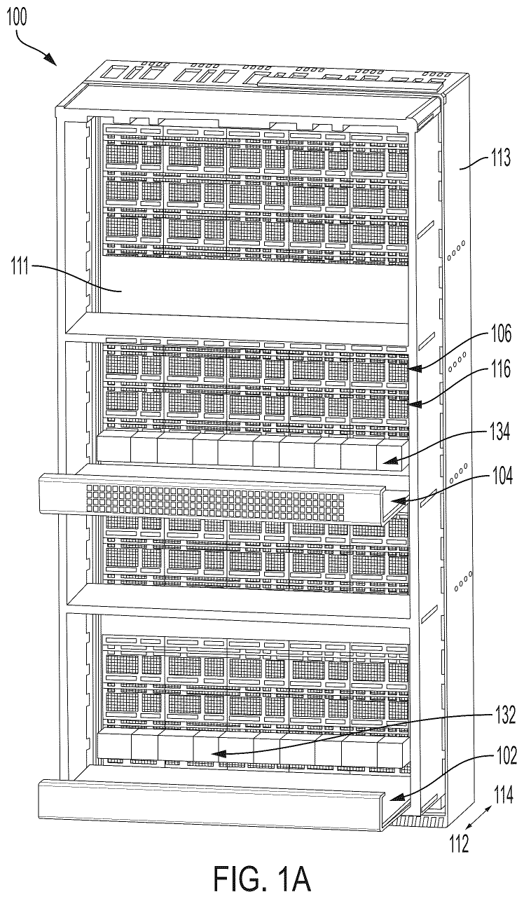

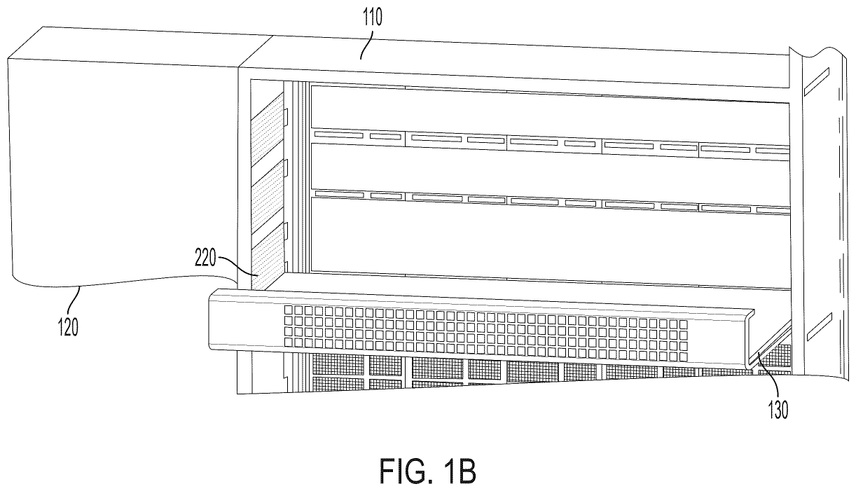

FIG. 1A is a front perspective view of a cabled backplane system 100. The cabled backplane system 100 may be used in a data communication application, such as in a network switch. As shown in FIG. 1A, the cabled backplane system 100 may interconnect daughter card assemblies, such as line cards 102 and switch cards 104 using cable harnesses 106. In this illustration, cable connectors 116 of the cable harnesses 106 are exposed for mating to mating connectors 132 on line cards 102, and/or mating connectors 134 on the switch cards 104. The cables of the cable harnesses 106 may be routed within a backplane cartridge 113. For simplicity of illustration, the cables of the wiring harnesses of the sideplane cartridge are not shown. The cables may be twinax or other high-speed cables.

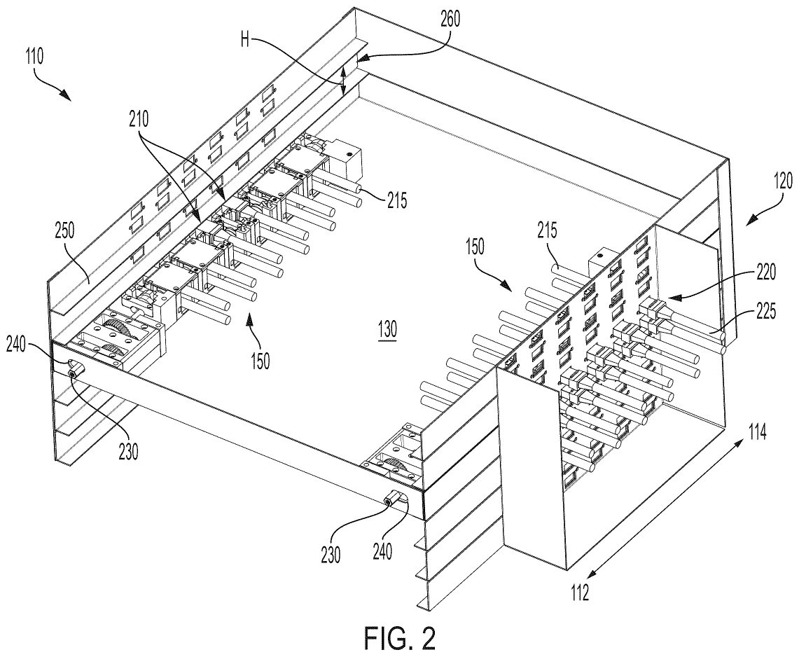

Cartridge 113 is illustrated at the back of a rack 110 into which assemblies, such as line cards 102 or switch card 104 can be inserted. When the illustrated computer system is used for other functions, the assemblies may have other formats, such as trays. FIG. 1A shows one line card 102 and one switch card 104 inserted into a rack 110 (FIG. 1B). Each is inserted into a slot 260 (FIG. 2). As can be seen, there are additional slots 260 in the rack 110 into additional assemblies might be inserted.

The rack 110 may include structures for guiding, supporting, and/or securing the line cards 102 and the switch cards 104 in the cabled backplane system 100. The cabled backplane system 100 may comprise one or more structures that may provide connections other than for the high speed signals routed through the cable harnesses 106. Backplane 111 is an example of such a structure. Backplane 111 may be a circuit board and may be manufactured from typical circuit board material, such as FR-4 material. Electrical components, such as power supplies, fans, connectors, and the like may be attached to the backplane 111. Such electrical components may be electrically connected to traces or circuits of the backplane 111. Couplings for passing cooling fluid to or from the assemblies inserted in the rack 110 may be attached to sideplane cartridge 120 or other structures at the back of the rack 110.

FIG. 1B shows a portion of rack 110, including three slots 260. This figure shows an alternative configuration in which the cable cartridge is configured for sideplane connections. As can be seen, the mating connectors 220 of the sideplane cable cartridge are on the sides orthogonal to the back of the rack 110. For this configuration, the connectors (such as connectors 134 in FIG. 1A) may be mounted at the sides of the electronic assemblies inserted into the rack 110. A connector assembly (e.g. 150, FIG. 2) may be used to move the connectors side to side on the electronic assemblies for mating or unmating with the connectors 220. Such a configuration may be useful, for example, if there is not sufficient space at the back of the rack for all desired high speed signal connections.

Trays are used herein as an example of assemblies that may be inserted into a rack. A rack may include any number of trays based on dimensions of the rack and the number of slots it is configured to support. The tray may include printed circuit boards or, for high performance systems, components interconnected with cables or other high speed interconnects. For simplicity of illustration all of the components within a tray are not expressly indicated. A front 112 of the rack and back 114 of the rack are indicated for explanatory purposes.

The trays may be inserted from the front 112 to the back 114. Insertion of the trays may engage connectors, such as for power or cooling fluid, on the back of the tray to complementary connectors at the back of the rack. When inserted, high speed connectors on the tray for mating to connectors of the sideplane cartridges may be in a retracted position. A connector assembly 150 may be used to mate connectors 210 (FIG. 2) of the tray with respective mating connectors 220 of the sideplane cartridge. Connector assembly 150 is further detailed in the following figures.

FIG. 2 shows portions of a rack according to an exemplary embodiment. A tray 130 is shown inserted into the rack 110. For simplicity of illustration, no components are shown on the tray 130, but components may be in the tray and may be, for example, connected to cables 215. In this example, the cables 215 are terminated to connectors 210 held of assemblies 150, one on each side of the rack. The cables 215 may couple components 140 on the tray 130 to other components via mating of the connectors 210 on the tray and mating connectors 220 of the sideplane cartridge 120.

For simplicity of illustration, FIG. 2 shows only a subset of the mating connectors 220 of the sideplane cartridge 120. In this example, the connectors that mate with connectors on the right side of tray 130 are visible. Holes are show where other connectors may be mounted. Likewise for simplicity, only a segment of the cables 225 terminating these connectors are shown. The rest of these cables may, for example, terminate other connectors that are inserted into the holes in the sideplane or may be routed elsewhere in the electronic system.

In the configuration shown in FIG. 2, covers are removed to expose the connector housing of two of the connectors 210. In some embodiments, covers may not be part of the assemblies 150 at all. In some embodiments, the tray 130 may have a cover that covers components 140 on the tray 130 and the assemblies 150.

In this example, rails 250 are arranged on each side of the rack so that a tray 130 may be placed on a pair of rails 250, one on each side of the rack 110, and inserted from the front 112 of the rack 110 to the back 114. In other examples, other structures may be used instead or in addition to rails to support trays in the rack. In this example, the space between adjacent rails 250 on the same side of the rack 110 defines a slot 260 and a slot height, which constrains a maximum tray height H that can be accommodated in the slot 260. In this example, the trays can have a height in the range of 40-50 mm, which may limit the size of an actuator in the tray to drive to connectors for mating.

At the front 112 of the rack 110, the tray 130 has an opening 240 on each side. Each opening 240 allows protrusion of an engagement feature 230 associated with the respective assembly 150. Engagement feature 230 may enable the assembly to be driven from outside the tray. The engagement feature 230 may be a keyway, as shown, a knob, or any other feature that facilitates engagement with the assembly 150, as further discussed. In FIG. 2, opening 240 is elongated in the side to side direction relative to the diameter of the shaft extending through it. Such a configuration enables side to side motion of the shaft, and the connector subassemblies coupled to it. The position of the engagement feature 230 within the opening as shown in FIG. 2 indicates that the connectors 210 and the mating connectors 220 are unmated. That is, the engagement features 230 are in a first position within their respective openings 240 in the tray 130.

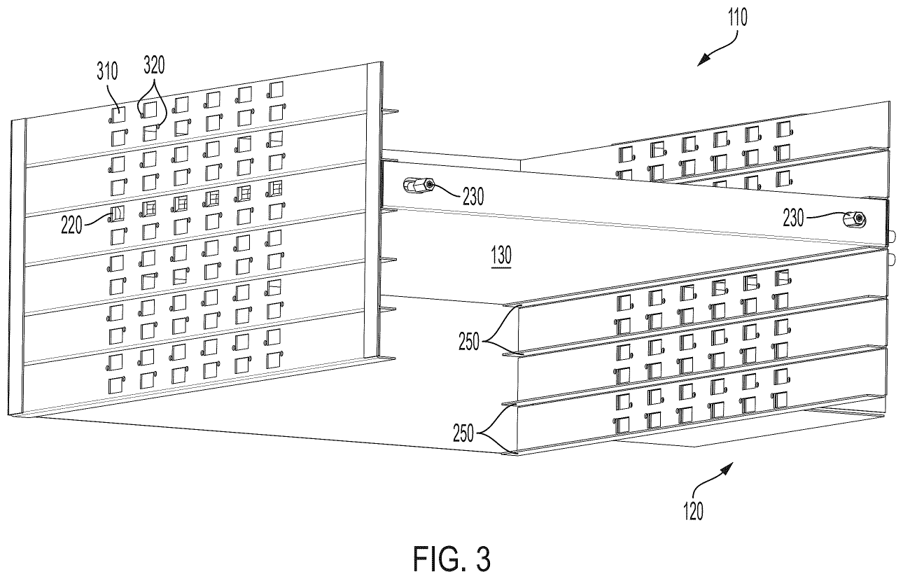

FIG. 3 shows a different view of the portions of the rack 110 shown in FIG. 2. A side of the rack 110 omitting the sideplane cartridge 120 is shown to expose connector openings 310 through which connectors, in this example terminating cables of a wiring harness of the sideplane cable cartridge, may be mounted.

In this example, connectors 210 on one side of the tray 130 are mounted in parallel columns. In this example each of the columns has two connectors, such that there are two rows of connectors on each side of a slot. In this example, each row has 6 connectors such that each connector assembly 150 makes connections for 12 connectors. Each of the connectors may have multiple signal paths through it, all of which may be completed when the connectors 210 are mated with the connectors 220 of the sideplane cable cartridge. FIG. 3 shows connectors 220 in one row installed, with others omitted for simplicity.

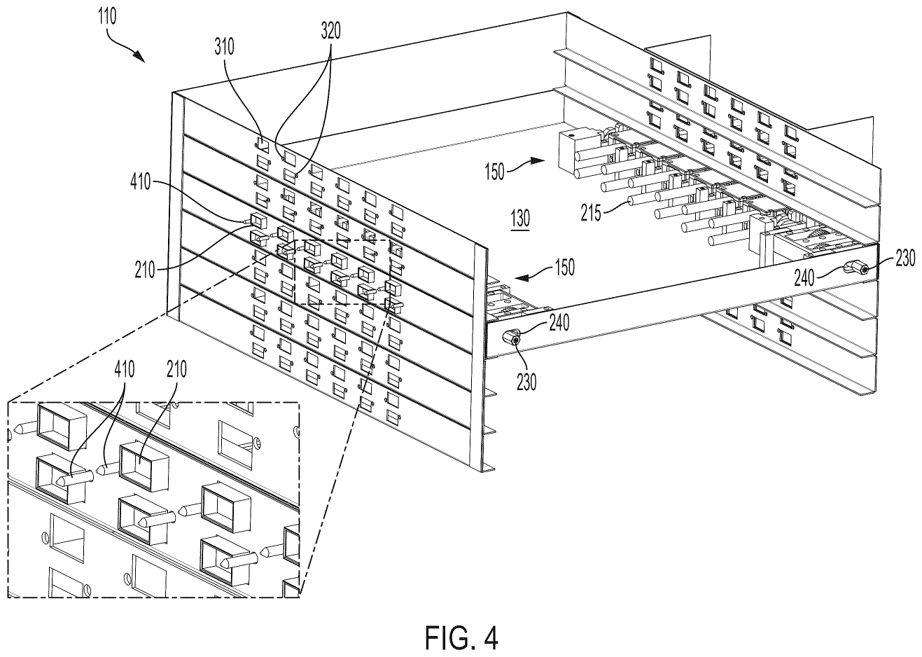

The mating interface of connectors 220 extend through connector openings 310 in the rack 110. The rack 110 may include guidance and/or float features to facilitate mating of connectors. In this example, rack 110 includes guide openings 320 to accommodate guideposts 410 (FIG. 4) of the assembly 150 that protrude through the guide openings 320 when the connectors 210 are in a mated arrangement with mating connectors 220 of the sideplane cartridge 120.

FIG. 4 shows a similar view to FIG. 3 but for connectors 210 moved into a mated position. An enlarged view of some of the connectors 210 shows protrusion of the connectors 210 through the connector openings 310 of the rack 110. In addition, guideposts 410 are shown protruding through guide openings 320 of the rack 110. With the connectors 210 in the mated position, as shown in FIG. 4, the engagement features 230 are in a second position within their respective openings 240. The change in position of the engagement features 230 as part of the mating process is discussed further.

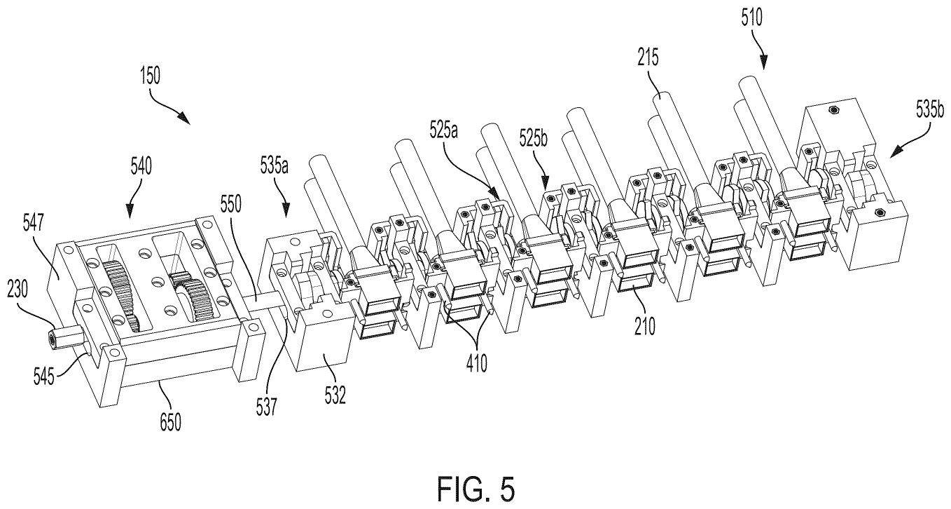

FIG. 5 shows an exemplary assembly 150 that may be used to mate connectors 210 on a tray 130 with connectors 220 of a sideplane cartridge 120 in a rack 110. The exemplary assembly 150 includes six subassemblies 510. Each subassembly 510 supports a column of connectors, which in this example is two connectors 210 in a stacked arrangement, as shown. Based on the maximum tray height H, which is limited by the height of the slot 260 that the tray 130 holding the assembly 150 will be slid into, one connector 210 or more than one connector 210 may be included in each subassembly 510. Further, when multiple connectors 210 are part of a subassembly 510, the connectors 210 may be side-by-side, in a row, and/or in a column, as shown in FIG. 5.

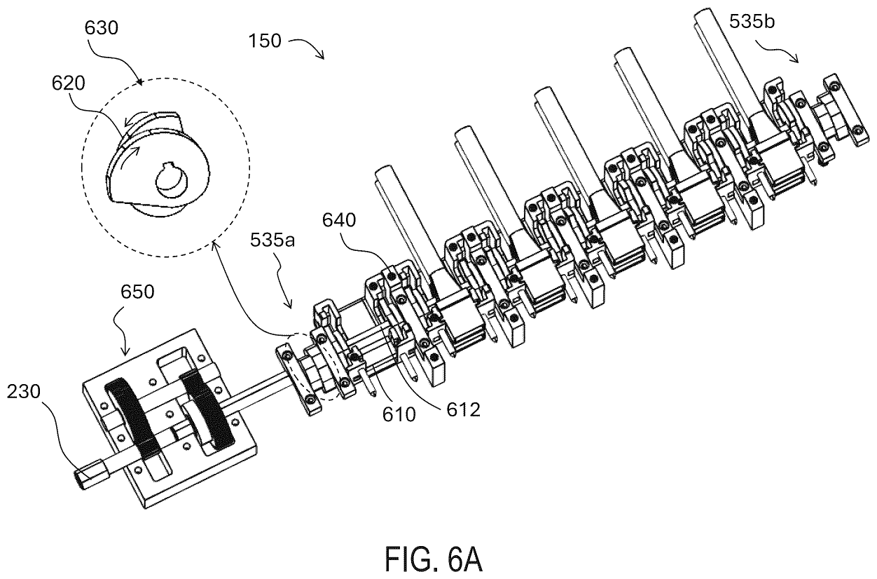

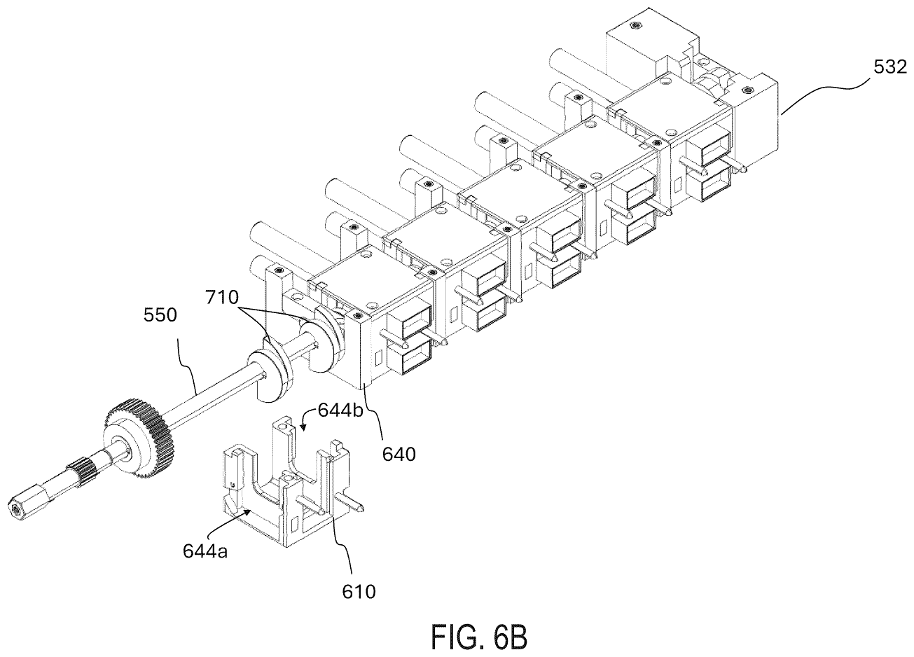

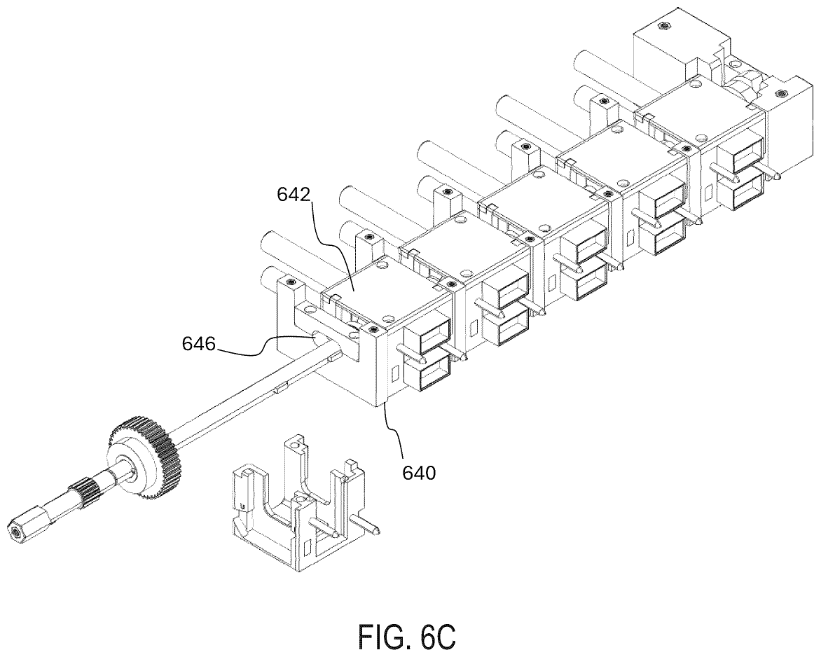

Each subassembly 510 may include one or more support members 610 (FIG. 6A) to support one or more connectors 210 held by the subassembly 510. Guidepost 410 may be a part of the subassembly to help align the connectors 210 with connector openings 310 of the rack 110. Guidepost 410 may optionally be attached to support member 610 as shown in FIG. 4. In the example illustrated in FIG. 6A, each support member 610 is configured to support both connectors in a column alone or in combination with a cover (such as cover 642, FIG. 6C), separators (such as separator 612, FIG. 6A), or other components that secure the connectors within support member 610.

Each subassembly 510 may also include one or more subassembly actuators. The actuators may move the connectors of the connector assembly in a sideways direction. The actuators, for example, may push the connectors outwards to mate with connectors of a sideplane cable cartridge, for example.

The actuators may include camming members. In this case, the camming members are coupled to a shaft 550 such that rotary motion of the shaft can be converted to linear motion of the connectors. The camming members in this case are bidirectional such that rotation of the shaft in one direction is translated to motion of the connectors towards an extended position and rotation of the shaft in the opposite direction is translated to motion of the connectors towards a retracted position. An example of a camming member is an eccentric element. To provide a bidirectional camming member in the illustrated example, a pair of eccentric elements in each actuator are mounted to the shaft and configured to bear against opposite sides of a support member 610 for the connectors.

In the example illustrated, each subassembly includes two actuators, illustrated as a first subassembly actuator 525a and a second subassembly actuator 525b. In this example, the subassembly actuators are positioned on opposite sides of the connectors and provide balanced force on the connectors when mating and unmating. Such an arrangement may reduce twisting motion of the connectors upon mating or unmating, reducing the chance of binding while mating or unmating, such that the assembly performs reliably.

In this example, support member 610 forms a portion of each of the subassembly actuators for a connector subassembly. As shown for example in FIG. 6B, support member 610 has openings 644a and 644b on either side of a central opening configured to receive connectors. These side openings 644a and 644b receive eccentric elements 710 mounted on shaft 550. In this example, the eccentric elements for both first subassembly actuator 525a and second subassembly actuator 525b in the same connector subassembly have the same shape and angular orientation. They are shaped to engage the inner walls of openings 644a and 644b over a certain range of angular positions of shaft 550. Rotation of the shaft in one direction within that range of angular positions will cause the eccentric element to push on the wall of the housing, which can extend the support member 610 relative to shaft 550. Such a motion moves the connectors of the subassembly in a sideways direction.

In the example illustrated, each subassembly actuator includes two eccentric elements one shaped to engage with an outer wall of support member 610 and drive the connectors in the support 610 toward the extended position when shaft 550 turns in one direction. The other eccentric element is shaped to engage with an inner wall of the of support member 610 and drive the connectors in the support 610 toward the retracted position when shaft 550 turns in the opposite direction.

Support member 610 may be integrated into the subassembly such that it may slide relative to shaft 550 and/or other components of the subassembly. In the illustrated example, support member 610 is not fixed directly to the tray. Rather, it is slidably mounted relative to the tray and/or shaft 550. A slidable mounting may be implemented by capturing the eccentric elements within support member 610 via cover 642.

In addition to the subassembly actuators associated with each subassembly 510, each assembly 150 may include one or more actuators associated with the full assembly 150. In the example of FIG. 5, the assembly includes two assembly actuators 535a and 535b, each on the end of a line of subassemblies, held side by side in the assembly. As with the actuators of each subassembly, a pair of actuators may reduce torque on the connectors during mating and unmating and enhance reliability of the mating and/or unmating process. Each of the first and second assembly actuators 535a, 535b is shown to be held in an actuator support 532 that has an actuator support opening 537.

In this example, assembly actuators 535a and 535b operate similarly to the subassembly actuators. Accordingly, the assembly actuators 535a and 535b include eccentric elements as described above in connection with the subassembly actuators. Rotation of the shaft in turn rotates the eccentric elements to apply a force in one direction or the opposite direction depending on the direction of rotation of the shaft. In the case of the assembly actuators 535a and 535b, that force is generated relative to actuator supports 532. Unlike support member 610, actuator support 532 may be secured to the tray such that the force generated by the eccentric elements moves shaft 550 relative to actuator support and relative to the tray. As can be seen, in FIG. 5, shaft 550 may pass through actuator support 532 via an actuator support opening 537 that is, like opening 240, elongated in the side to side direction. That elongated opening is part of a slidable shaft mounting that enables the shaft to move toward the extended position or towards the retracted position.

As with the subassembly actuators, the eccentric elements of assembly actuators 535a and 535b are shaped and positioned to drive shaft 550 over only a range of angular positions of shaft 550. In the illustrated embodiment, that range of angular positions is different from the range of shaft positions over which any of the subassembly actuators drives its respective support member 610. Such a configuration enables rotation of the shaft over the range of angular positions in which assembly actuators 535a and 535b are to first drive shaft 550 towards the engagement position, moving with it all of the connector subassemblies in unison. Further rotation of the shaft outside of that first range may then sequentially place the shaft in the angular range in which the subassembly actuators engage. As the subassembly actuators may be configured to engage in different angular ranges, each subassembly actuator may engage at different times, as its range of angular rotation on the shaft is reached. In this way, the subassemblies may, after moving together, move sequentially such that the connectors of the subassemblies engage mating connectors at different times, thereby distributing the maximum mating force for the connector subassemblies over time. Such a pattern of motion has been found to enable a relatively large range of motion, with relatively low mating force, in a relatively low height.

In the illustrated example, the actuators for the assembly and actuators for the connector subassemblies may have approximately the same maximum radius and may provide approximately the same amount of travel for the connectors they push. In some examples, this range of travel may be on the order of 10-15 mm, such as approximately 12 mm of travel, for a total travel of around 24 mm when both assembly and subassembly actuators are used to push connectors in a mating and/or unmating direction.

An assembly drive mechanism 540 is configured to rotate shaft 550. In some examples, drive mechanism 540 may be configured to reduce the maximum force, applied as a torque on engagement feature 230, required for mating all of the connectors. In the illustrated example, engagement feature 230 is coupled through gears of drive mechanism 540 to shaft 550 such that rotation of engagement feature 230 causes rotation of shaft 550. In this example, the gears of drive mechanism 540 are sized to reduce the torque required to rotate shaft 550 that extends through the actuator 530 and subassemblies 510. That gearing ratio, for example, may be in the range of 8:1 to 15:1, such as 12:1, requiring a torque on engagement feature 230 about one twelfth that required at shaft 550 to drive any of the assembly or subassembly actuators.

Assembly drive mechanism 540 may be configured to support a side to side motion of shaft 550. In the example illustrated, an opening 545 in the housing 547 of the assembly drive mechanism 540 facilitates movement of the shaft 550. Further, the gears coupled to shaft 550 may be part of a floating drive mechanism 650 (FIG. 6A). The floating drive mechanism 650 may be captured within a housing 547 (shown without a cover in FIG. 5, which may be used to capture the floating drive mechanism 650 within the housing). In this way, shaft 550 may be driven, but may also move into a position dictated by the engagement of eccentric elements within the actuator supports 532 based on angular position of the shaft.

FIGS. 6A-6C show aspects of the exemplary assembly 150 of FIG. 5. The floating drive mechanism 650 is exposed by omitting the housing 547. In this example, the arrangement of the assembly drive mechanism 540 implements a gear ratio (e.g., 12 to 1) that reduces the force required to rotate the shaft 550 by rotating the engagement feature 230. The connectors 210 are removed from one of the subassemblies 510 to expose the support member 610 that support connectors 210 of that subassembly 510. A separator 612 that may also be loaded in the support structure to set the spacing between connector or otherwise secure the connectors in the support structure is shown. The support structures around the first assembly actuator 535a and the second assembly actuator 535b are also omitted.

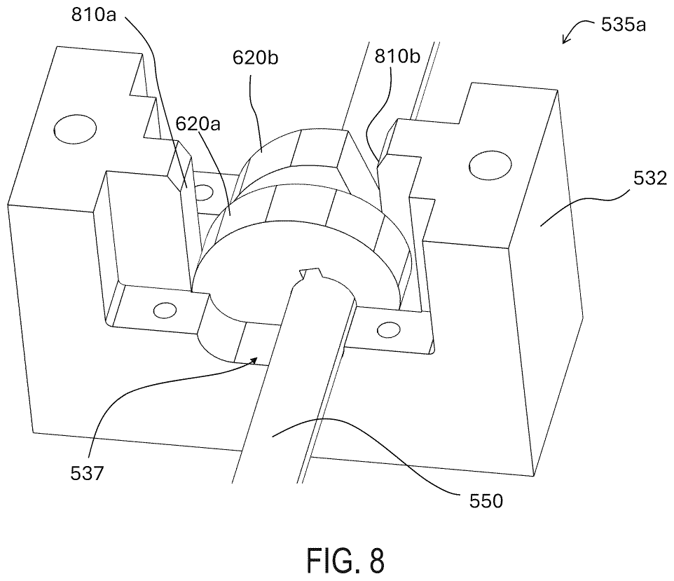

The exemplary first assembly actuator 535a and the second assembly actuator 535b, shown in greater detail in FIG. 8, each includes a pair 630 of eccentric elements 620. As shown in the enlarged view of the first assembly actuator 535a, the eccentric elements 620 may act as a pair of cams. As indicated by the arrows, the pair 630 of eccentric elements 620 may be used so that one eccentric element 620 facilitates forward drive while the other facilitates reverse drive by the first and second assembly actuators 535a, 535b. That is, one of the eccentric elements 620 facilitates mating the connectors 210 and the mating connectors 220, while the other eccentric element 620 of the pair 630 facilitates disconnecting the connectors 210 and the mating connectors 220.

The eccentric elements 620a and 620b of the first and second assembly actuators 535a, 535b move the shaft relative to the housing 547. The eccentric elements 620 may move the shaft 550 relative to the tray 130, as discussed with reference to FIGS. 2 and 4. During the mating process, this motion provides a first phase in which all the subassemblies 510 and, thus, all the connectors 210 within the subassemblies 510 move in unison.

That is, according to the arrangement shown in FIGS. 6A-6C for the exemplary assembly 150, when the engagement feature 230 is rotated clockwise over an angular distance, the first and second assembly actuators 535a, 535b of the actuator 530 move all the subassemblies 510 toward the side edge of the tray 130 (toward the connector openings 310).

FIG. 6B is a partially exploded view of the connector assembly showing support 610 for one of the connector subassemblies exploded from the assembly, revealing eccentric elements 710. FIG. 6C is the same exploded view as FIG. 6B, with the eccentric elements 710 hidden to reveal support components, and also to reveal mounting features on shaft 550 at which eccentric elements may be attached in a predefined angular orientation.

To provide mechanical support to the assembly 150, one or more components may be fixed to the tray but may be configured to allow relative motion of floating components such as support 610. In this example, an actuator support 532 may be one such support component, providing support for the end-most subassembly in the row. For the interior subassemblies, shaft mounting separators 640 may be used. As with actuator supports 532, shaft mounting separators 640 may be fixed to the tray. In this example, they are fixed top and bottom to the cover of the tray and to a bottom of the tray. Shaft mounting separators 640 may also include elongated holes 646, acting as bearings for the shaft while enabling the shaft to slide in a side to side direction. These support components, whether actuator supports 532, shaft mounting separators 640 or other similar components define channels in which the supports 610 for the subassemblies may slide in outward or inward directions, while restraining twisting of the support 610. As can be seen in FIG. 6C, shaft mounting separators 640 (as with other components that support the shaft) may be formed in multiple pieces, such as a base and a clamping piece screwed or otherwise secured to the base to capture the shaft within elongated holes 646.

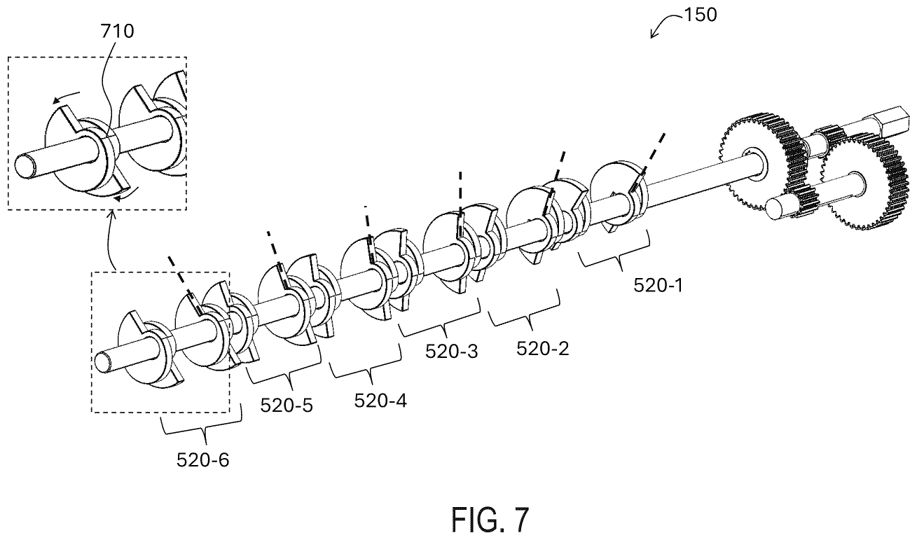

FIG. 7 shows portions of the subassemblies 520-1 through 520-6 and, more specifically, the eccentric elements 710 that may form a part of each subassembly actuator 525a and 525b. The eccentric elements 710 of each subassembly actuator 525a, 525b may act as a pair of cams, for example. As shown in FIG. 7, the eccentric elements of the first subassembly actuator 525a and the second subassembly actuator 525b are in the same position for a given subassembly. Among the subassembly actuators for different subassemblies, the position of the pair of eccentric elements 710 differs. This variation of position is illustrated with a dashed line aligned with one of the pair of eccentric elements 710 for each of the subassemblies 520-1 through 520-6. The dashed lines also indicate that the difference in position among the pair of eccentric elements 710 for each of the subassemblies 520-1 through 520-6 is sequential, advancing in this example by a fixed angular amount from subassembly to subassembly from the proximal end of shaft 550 near the drive mechanism towards the distal end. This sequential difference in position facilitates sequential movement of the subassemblies 510.

FIG. 8 details aspects of the actuator support 532 and the interaction with the eccentric elements 620a, 620b of the first or second assembly actuators 535a, 535b of an actuator 530. In the example of FIG. 5, the assembly actuators and the subassembly actuators operate on the same principle such that the principles of operation described in connection with FIG. 8 may also be applicable to the subassembly actuators 525a and 525b.

In the example of FIG. 8, the actuator support 532 includes a protruding support wall 810a that the eccentric element 620a contacts to move the associated subassembly 510 to the right, according to the orientation shown in FIG. 8. Similarly, the actuator support 532 also includes a protruding support wall 810b that the eccentric element 620b contacts to move the associated subassembly 510 to the left. In the exemplary illustration, shaft 550 has been pushed to the right-most end of opening 537 by pressing of eccentric element 620a against wall 810a. That is, the eccentric elements 620 cause motion of the subassemblies 510 toward the extended position for a particular radial distance traveled by the shaft 550, specifically that range over which a portion of the eccentric element 620a contacts support wall 810a until the largest diameter portion of the eccentric element contacts the wall.

If the shaft is rotated counterclockwise, shaft 550 will move to the left, and movement would stop when the largest diameter portion of the eccentric element 620b contacts the support wall 810b. To retract the connectors, the shaft may be rotated counterclockwise and a portion of eccentric element 620b would eventually contact support wall 810b, with increasingly larger radius potions contacting support wall 810b as the shaft is rotated further, pushing the shaft towards the other side of actuator support opening 537. Concurrently with that rotation, the radius of the portion of eccentric element 620a contacting support wall 810a would decrease, clearing the way for that motion of shaft 550.

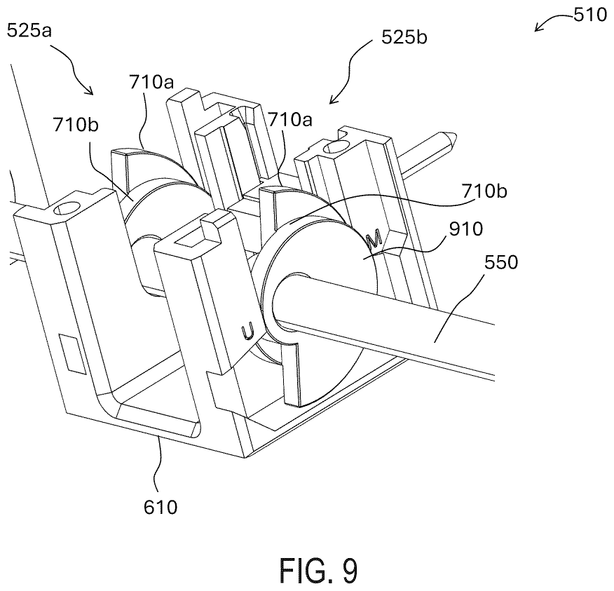

FIG. 9 details aspects of the first and second subassembly actuators 525a, 525b of a subassembly 510, which operates on the same principle, though with differences in what components the eccentric elements but against and with differences of the angular orientation of the eccentric elements and, in some examples, their shape. Eccentric elements 710a, 710b associated with each of the first and second subassembly actuators 525a, 525b are shown. As shown, both eccentric elements 710a are in the same position, and both eccentric elements 710b are in the same position. Both eccentric elements bear against walls of the support 610, pushing the subassembly towards the engaged position or, alternatively, towards the disengaged position over the range of angular positions in which rotation of the shaft brings a portion of the eccentric element with a larger radius into contact with the wall of the support 610.

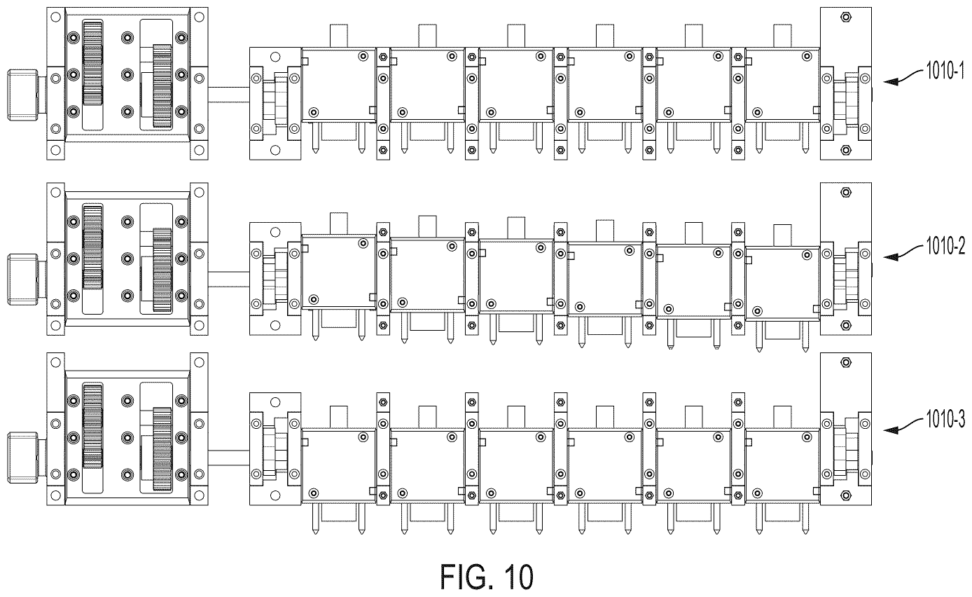

FIG. 10 illustrates a series of steps in a connector mating process, showing an unmated stage 1010-1 in which the connectors are in a fully retracted position, sequentially mated stage 1010-2, and mated stage 1010-3 of the connectors 210 of an assembly 150 in which all of the connectors are in a fully extended position. A dashed line is used to indicate the relative position of the connectors 210 of the different subassemblies 510 in the sequentially mated stage 1010-2. A comparison of this dashed line with a straight, solid line indicates the sequentially increasing distance from the solid line for subassemblies from right to left according to the orientation in FIG. 10.

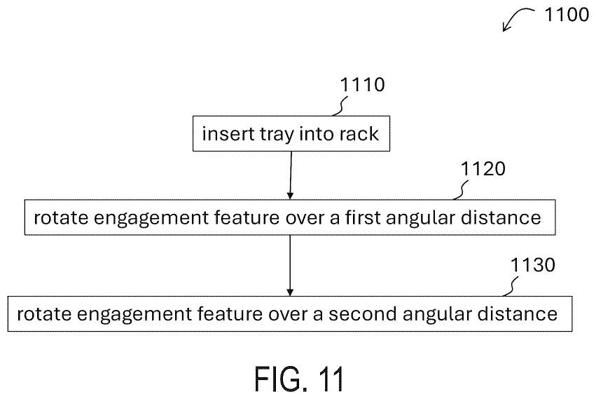

FIG. 11 shows a process flow of a method 1100 of engaging a tray 130 in a rack 110 using aspects of the assembly 150 discussed herein. At 1110, inserting a tray 130 into a rack may include pushing the tray 130 along the rails 250, one on each side of the rack 110, until the tray 130 is properly positioned within the rack 110. At 1120, rotating the engagement feature 230 over a first angular distance refers to the first phase of mating during which all the subassemblies 510 are moved in unison toward the edge of the tray 130 and the connector openings 310 in the rack 110. At 1130, rotating the engagement feature 230 over a second angular distance refers to the second phase of mating during which the subassemblies 510 move sequentially, as shown in FIG. 10.

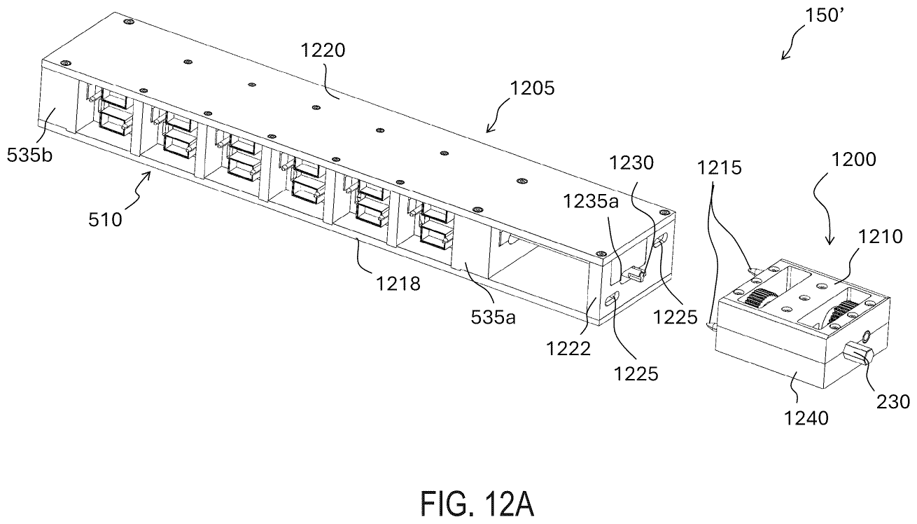

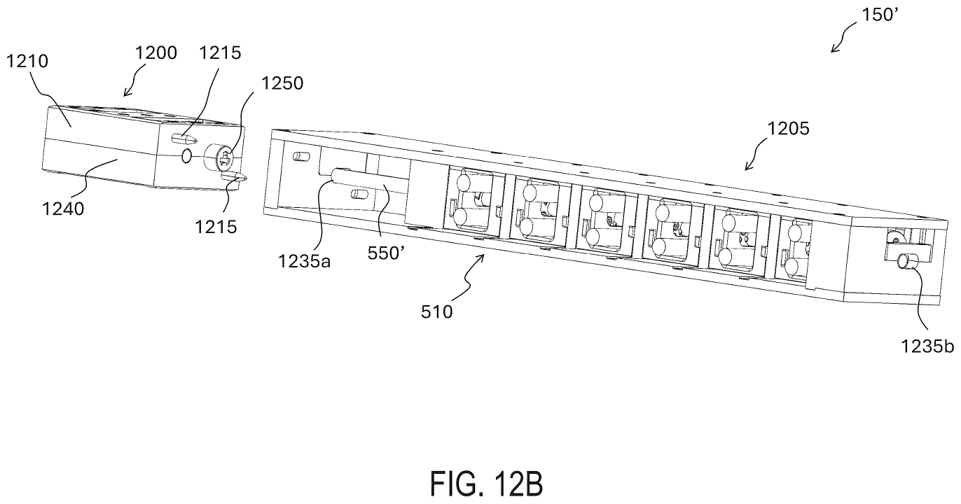

FIGS. 12A through 14 illustrate aspects of some embodiments in which the assembly 150′ includes a separable assembly drive mechanism 1200 and connector actuator component 1205 including, for example, subassemblies 510 and subassembly actuators 525a, 525b. In the example, illustrated, a separable interface is provided between the assembly drive mechanism 1200 and connector actuator component 1205 that enables both translation and rotation of a shaft passing through the connector actuator component 1205, which supports motion of the connectors of the connector actuator component 1205 in unison and in staggered fashion, as described above. In some examples, elements identified in FIGS. 12A through 14 with reference numbers as in FIGS. 1-11 may be as described above.

According to embodiments with a connector actuator component 1205 that is separate from the assembly drive mechanism 1200, the connector actuator component 1205 may require less space on the tray 130 and/or operate at lower cost as compared with the integrated assembly shown in FIG. 5, for example. As a specific example, in comparison to FIG. 4 in which the assembly drive mechanism 540 is mounted adjacent to the edge of the tray, connector actuator component 1205 may be mounted adjacent the edge of a tray. For driving connectors for mating and/or unmating, assembly drive mechanism 1200 may be pressed against connector actuator component 1205 from outside the tray. In this way, space need not be allocated on the tray for the assembly drive mechanism 1200.

Not mounting the assembly drive mechanism 1200 on the tray may reduce the space occupied by the connector assembly along the side of the tray. Alternatively or additionally, the assembly drive mechanism 1200 may be made taller, in a direction perpendicular to the plane of the tray, than the tray itself. An assembly drive mechanism 1200 that is unconstrained by the height of the tray 130 can have gears that are larger than those of the assembly drive mechanism 540 included on the tray 130 with the remainder of the assembly 150. Larger gears may enable a larger gearing ratio, which may be advantageous when driving connectors against a large force.

In some examples, the assembly drive mechanism 1200 may be attached to a power tool to rotate the engagement feature 230 and, in turn, the shaft 550′. That attachment may be made to engagement feature 230. In some examples, the interface between the assembly drive mechanism 1200 and the connector actuator component 1205 may be keyed differently to prevent the use of a conventional power tool from being used to rotate the shaft 550 of the connector actuator component 1205. In the example illustrated, assembly drive mechanism 1200 has a keyed socket 1250, with a shape complementary to keyed shaft end 1230. As can be seen, the socket 1250 is configured to receive a shaft with multiple (three in this example) lobes.

FIG. 12A is a perspective view of an assembly 150′ with a separable assembly drive mechanism 1200 according to some embodiments. A cover 1210 of the assembly drive mechanism 1200 and a cover 1220 of the connector actuator component 1205, housing the subassemblies 510 and assembly actuators 535a, 535b on each end of a line of subassemblies 510, are shown. An end wall 1222 and the assembly actuator 535b define the two ends of the connector actuator component 1205. In this example, connector actuator component 1205 is illustrated with a substrate 1218 to which assembly actuators 535a and 535b may be attached. Such a substrate 1218 may be, for example, a metal plate. In some examples, substrate 1218 may be a portion of a tray or other component of an electronic system utilizing a connector assembly that provides suitable support.

A keyed shaft end 1230 facilitates an interface between the shaft 550 that goes through the subassemblies 510 and a shaft 1410 (FIG. 14) of the assembly drive mechanism 1200. The keyed shaft end 1230 may be shaped so that it does not interface easily with an ordinary power tool, thereby preventing the use of a tool other than the assembly drive mechanism 1200 to turn the shaft 550′and move the subassemblies 510 of the connector actuator component 1205.

The keyed shaft end 1230 is shown emerging from a first shaft slot 1235a in the end wall 1222. A second shaft slot 1235b is on the other end of the subassemblies 510, as shown in FIG. 12B. Such slots enable shaft 550 to translate, driving the connector subassemblies in unison, as described above.

Guide slots 1225 are shown on either side of the keyed shaft end 1230. Guide pins 1215, protruding from assembly drive mechanism 1200 may fit within the guide slots 1225 when assembly drive mechanism 1200 is engaged to connector actuator component 1205. In the example illustrated, one guide pin 1215 protrudes from the cover 1210 and one protrudes from the housing 1240 of the assembly drive mechanism 1200end wall 1222. The pin and slot engagement enables assembly drive mechanism 1200 to slide with shaft 550′without rotating. The shaft slots 1235a, 1235b and guide slots 1225 are shaped to facilitate lateral movement of the shaft 550, based on rotation of the shaft 550′caused by rotation of the engagement feature 230 over the first angular distance during the first phase of mating, as described with reference to FIG. 11. The shape of the shaft slots 1235a, 1235b and guide slots 1225 may be similar to those of the opening 545 in the housing 547, discussed with reference to FIG. 5, and elongated holes 646 in the shaft mounting separators 640, discussed with reference to FIG. 6C. The opening 545 in the housing 547 may be omitted in the housing 1240 of the assembly drive mechanism 1200, as discussed with reference to FIG. 14.

FIG. 12B is a perspective view of the assembly 150 of FIG. 12A from a different side. The view in FIG. 12B shows a keyed socket 1250 of the assembly drive mechanism 1200 that may interface with the keyed shaft end 1230 of the shaft 550′ extending through the connector actuator component 1205. The guide pins 1215 are also shown, one extending from the cover 1210 (the left guide pin 1215 in FIG. 12B), and one extending from the housing 1240 (the right guide pin 1215 in FIG. 12B) in this example, but the location of the guide pins and corresponding slots may be varied in other examples. The second shaft slot 1235b at the opposite end of the connector actuator component 1205 from the first shaft slot 1235a is also visible.

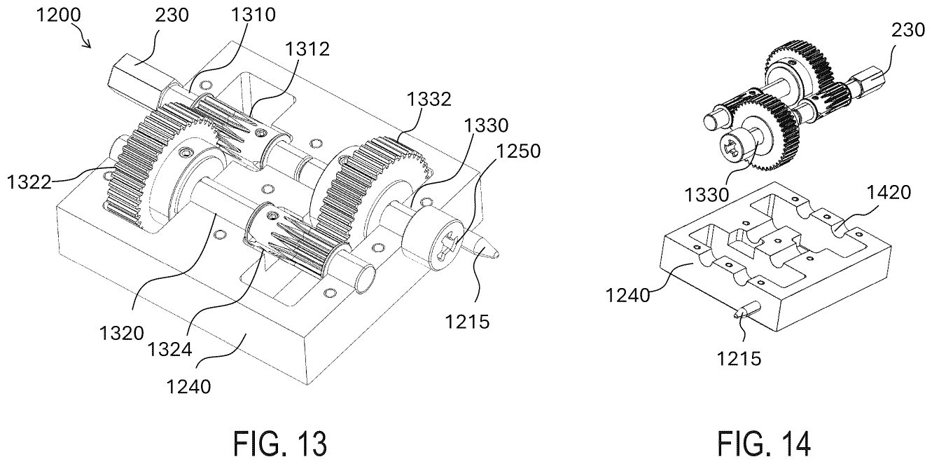

FIG. 13 is a perspective view of the assembly drive mechanism 1200, with cover 1210 removed, according to some embodiments. The guide pin 1215 extending from the housing 1240 of the assembly drive mechanism 1200 is also shown.

The view in FIG. 13 reveals that the keyed socket 1250 is coupled to the engagement feature 230 via a reducer. In this example, engagement feature 230 is mounted on a shaft 1310, as is a small gear 1312. Small gear 1312 engages large gear 1322, which is mounted on shaft 1320, as is small gear 1324. Small gear 1324 engages large gear 1332, which is mounted on shaft 1330, with keyed socket 1250 forming or attached at a distal end of shaft 1330.

Thus, when the assembly drive mechanism 1200 is engaged with the connector actuator component 1205 by inserting the guide pins 1215 into the corresponding guide slots 1225 and interfacing the keyed socket 1250 with the keyed shaft end 1230, rotating the engagement feature 230 of the assembly drive mechanism 1200 facilitates rotating the shaft 550′that goes through the subassemblies 510 in the connector actuator component 1205, enabling shaft 550′to perform the functions of shaft 550 as described above.

The housing 1240 and/or cover 1210 may provide bearing surfaces for shafts, such as shafts 1310, 1320 and/or shaft 1330. FIG. 14 is an exploded view of the portion of assembly drive mechanism 1200 shown in FIG. 13. In this example, recesses 1420 formed in housing 1240 provide bearing surfaces for corresponding shafts. Though cover 1210 is not visible in the illustrated view, complementary recesses in cover 1210 may bound the shafts, restraining translation of the shafts with respect to the housing and/or cover. Nonetheless, translation of the shaft 550′ may be supported as a result of the interface between assembly drive mechanism 1200 and connector actuator component 1205.

The guide pin 1215 protruding from the housing 1240 is visible in this view. As described with reference to FIG. 11, during the first phase of mating of connectors to a sideplane, rotation of the shaft 550′ caused by rotation of the engagement feature 230 causes all the subassemblies 510 to move in unison toward the side edge of the tray 130 and the connector openings 310 in the rack 110. The shaft 550′ also moves laterally with the subassemblies 510 during this first phase. As discussed with reference to FIG. 6C, for example, elongated holes 646 in shaft mounting separators 640 may accommodate this side-to-side movement of the shaft 550′.

In embodiments with a separate assembly drive mechanism 1200 and connector actuator component 1205, as shown in FIGS. 12A and 12B, for example, the shaft slots 1235a, 1235b on either end of the connector actuator component 1205 accommodate this lateral movement of the shaft 550′. However, the assembly drive mechanism 1200 need not accommodate lateral movement of the shaft 1410 that couples to shaft 550′ because movement of the assembly drive mechanism 1200 is not constrained on the tray 130 as in the embodiments discussed with reference to FIGS. 5-6C. That is, the shafts, such as shafts 1310, 1320 and 1330, within the assembly drive mechanism 1200 that couples the engagement feature 230 and keyed socket 1250 rotate but need not translate within the housing 1240 of the assembly drive mechanism 1200 when the shaft 550′ moves within the shaft slots 1235a, 1235b and in the connector actuator component 1205. This is because the entire assembly drive mechanism 1200 can move with the shaft 550′ as the engagement feature 230 is being rotated during the first phase of mating the subassemblies 510 to the rack 110. Thus, in the example illustrated, the housing 1240 of the assembly drive mechanism 1200 does not include an opening 545 that accommodates side-to-side movement, as shown and discussed with reference to FIG. 5. Instead, as shown in FIG. 14, recesses 1420 accommodating rotation but not lateral movement of shaft 1410 in the assembly drive mechanism 1200 are adequate.

Having thus described at least one embodiment, it is to be appreciated that various alterations, modifications, and improvements may readily occur to those skilled in the art. Such alterations, modifications, and improvements are intended to be within the spirit and scope of the invention. Accordingly, the foregoing description and drawings are by way of example only.

Various changes may be made to the illustrative structures shown and described herein. As a specific example of a possible variation, collections of components that interoperate were described as an assembly or a subassembly. It is not a requirement that these components be assembled into a discrete structure. The same collection of components, for example, may be assembled when an equipment rack is assembled.

As another example of a variation, a try was used as an example of an electronic assembly that may be inserted into a rack, but the connector assembly as described herein may be used on an electronic assembly of any desired form.

Further, the connector assembly was illustrated oriented for mating with a sideplane cable cartridge. Connector assemblies as described herein may be mounted for mating with other components, such as a backplane cable cartridge or a conventional backplane, or midplane or for mating with connectors in a direct mate orthogonal architecture in which there is no plane.

As yet another example, connector subassemblies were illustrated in which each column of connectors at a side of a tray was mounted to the same subassembly and each subassembly moved independently. Other combinations are possible. Multiple columns of connectors may be mounted to the same subassembly, or more than one subassembly may move at a time.

Further, a connector assembly with a single shaft was illustrated. A tray may include multiple subassemblies, which may be driven separately. Alternatively, a connector assembly may have multiple shafts that are driven together. Whether driven together or separately, the shafts may be parallel for example, such that connectors in each of multiple rows are moved by rotation of a respective shaft.

Also, connectors were described as mounted to support members of a connector subassembly. It is not a requirement that the support member be separately manufactured from the connector. In some examples, the support member may be manufactured, for example, as part of the connector housing.

Further, multiple components were described mounted on a single shaft. Such a shaft may be formed as an integral member or may be formed by multiple interconnected, axially aligned segments.

As yet another example, motion in two phases was described. In some scenarios, the tray height may be large enough or the total travel distance needed for the connectors may be small enough that only one phase of motion may be used. For example, only the connector subassembly actuators might be used for moving the connectors sequentially. Features included to support motion of the connector subassemblies in unison might be omitted. The assembly actuators might be omitted, for example, as well as features of the drive mechanism to support floating might be omitted to simplify construction of the connector assembly.

Further, eccentric members were described as an exemplary implementation of a camming member. A cam of other shape may alternatively or additionally be used in one or more of the actuators described herein.

As yet another example, movement of subassemblies in the connector assembly was described as being sequential. In some embodiments, multiple subassemblies may move concurrently even in a sequential mating phase. Such a configuration may be achieved, for example, by configuring the eccentric elements within the subassembly actuators to concurrently engage their respective supports 610 over a portion of the mating cycle. For example, when mating connectors, there may be a range of relative separation of the connectors when the mating force is higher than for other separations. Reduced maximum mating force may be achieved by driving only one of a subset of the connector subassemblies through the region of maximum mating force at a time. Accordingly, in some examples, the drive for the subassemblies may be staggered, rather than sequential. The stagger, for example, may approximate or exceed, the distance over which connectors, when pushed together for mating, experience their maximum mating force (and/or conversely the distance over which the connectors when separate experience their maximum unmating force).

Moreover, complementary features were described, such as guide pins on a first component and slots receiving those guide pins on a second component. In alternative examples, the components may be reversed, with the guide pins on the second component and slots or the first component. As another alternative, the components could be mixed, with a slot and guide pin on both the first and the second components.

Further, a connector assembly supporting a mating sequence of connectors to distribute mating force over time was illustrated configured to support mating those connectors to a sideplane was illustrated. Techniques as described herein may alternatively or additionally be used to support connector mating in other locations with n an electronic system, such as at a backplane.

As yet an example of another variation, a mating sequence was described in which multiple connectors move together over a first portion of the sequence and move in staggered fashion over a second portion of the sequence. In other examples, a connector subassembly may implement only one of these two portions. Also, a connector subassembly may implement of operations in other phases of the mating sequence in conjunction with either or both of the described portions of the mating/unmating sequence.

In a first example, an assembly may include a plurality of subassemblies each comprising one or more support members configured to respectively receive one or more electrical connectors. The assembly may also comprise a subassembly actuator configured to drive the one or more support members of the subassembly relative to the one or more support members of other subassemblies.

Optionally, the assembly may further comprise a first assembly actuator configured to drive the plurality of subassemblies in unison. In some embodiments, assembly may further comprise a second assembly actuator, and the plurality of subassemblies may be between the first assembly actuator and the second assembly actuator.

Optionally, each of the first and second assembly actuators may include a bidirectional camming element comprising a first eccentric element and a second eccentric element with the same shape as the first eccentric element, where the bidirectional camming element may be configured to drive the plurality of subassemblies when rotated.

Optionally, the first and second assembly actuators may be configured to move each of the plurality of subassemblies a same distance in unison during a first phase, and the subassembly actuator of each of the plurality of subassemblies may be configured to move a respective subassembly during a second phase such that the plurality of subassemblies move sequentially during the second phase. In some embodiments, an amount of the same distance may be based on a height of a slot accommodating the assembly. In some embodiments, an amount of the same distance may be at least 1 millimeter (mm) per 5 mm height of the slot and the same distance may be greater than 10 mm.

Optionally, the subassembly actuator may be a first subassembly actuator and each of the plurality of subassemblies may further comprise a second subassembly actuator, and the one or more support members may be between the first and second subassembly actuators. In some embodiments, the first and second subassembly actuators may respectively include a camming element configured to drive the one or more support members when rotated.

Optionally, the support member of each subassembly of the plurality of subassemblies may be configured to support at least two electrical connectors. In some embodiments, the at least two electrical connectors of each subassembly may be in a stacked arrangement. In some embodiments, the at least two electrical connectors of each subassembly may be in a side-by-side arrangement.

Optionally, the plurality of subassemblies may be driven sequentially based on sequential actuation by the subassembly actuators of each of the plurality of subassemblies.

Optionally, the assembly may be disposed on a tray and the one or more electrical connectors of each of the plurality of subassemblies may be mated to a corresponding mating connector in a rack into which the tray may be inserted.

In a second example, an assembly may include a plurality of subassemblies each comprising one or more support members configured to respectively receive one or more electrical connectors. The assembly may also comprise an actuator configured to drive the plurality of subassemblies in unison.

Optionally, the actuator may be a first actuator and the assembly may further comprise a second actuator, and the plurality of subassemblies may be between the first and second actuators. The first and second actuators may respectively include a first eccentric element and a second eccentric element with a same shape as the first eccentric element, where the first and second eccentric elements may be configured to drive the subassemblies when rotated. The first and second actuators may be coupled to the subassemblies such that each of the subassemblies move a same distance in unison during a first phase. In some embodiments, an amount of the same distance may be based on a height of a slot accommodating the assembly. In some embodiments, an amount of the same distance may be at least 1 millimeter (mm) per 5 mm height of the slot and the same distance may be greater than 10 mm.

Optionally, each subassembly may include a subassembly actuator configured to drive the one or more support members of the subassembly relative to the one or more support members of other subassemblies. The subassembly actuator may be a first subassembly actuator and the subassembly may further comprise a second subassembly actuator. The one or more support members may be between the first and second subassembly actuators. The first and second subassembly actuators may each include a first subassembly eccentric element and a second subassembly eccentric element with a same shape as the first eccentric element. The first and second subassembly eccentric elements may be configured to drive the one or more support members when rotated.

Optionally, each subassembly may include at least two support members configured to respectively receive at least two electrical connectors in a stacked arrangement.

Optionally, each subassembly may include at least two support members configured to respectively receive at least two electrical connectors in a side-by-side arrangement.

Optionally, the assembly may be disposed on a tray and the one or more electrical connectors of each subassembly may be mated to a corresponding mating connector in a rack into which the tray may be inserted.

In a third example, a method of mounting a tray in a rack is provided. In some embodiments, the tray may include an assembly comprising a plurality of subassemblies, and each of the subassemblies may include one or more support members configured to respectively receive one or more electrical connectors. The assembly may also comprise an actuator configured to drive the plurality of assemblies. The method of mounting the tray may comprise inserting the tray into the rack and rotating a shaft coupled to the actuator and the subassemblies in a first rotational direction over a first angular distance over which the plurality of subassemblies move together.

Optionally, the method may further comprise rotating the shaft in a first rotational direction over a second angular distance over which the plurality of subassemblies move sequentially. The method may further comprise mating the one or more electrical connectors of each of the subassemblies with corresponding connectors of the rack while rotating the shaft over the second angular distance. The method may further comprise rotating the shaft in a second rotational direction opposite the first rotational direction to unmate the one or more electrical connectors of each of the subassemblies from corresponding mating connectors of the rack.

In a fourth example, a method of mounting a track in a rack is provided. In some embodiments, the tray may include an assembly comprising a plurality of subassemblies, and each of the subassemblies may include one or more support members configured to respectively receive one or more electrical connectors. The assembly may also comprise an actuator configured to drive the plurality of subassemblies in unison. The method may comprise inserting the tray into the track and rotating a shaft in a first rotational direction to engage the actuator over a first angular distance over which the subassemblies move sequentially to mate with respective connectors in a side plane of the rack.

Optionally, the method may further comprise rotating the shaft in the first rotational direction over a second angular distance over which the subassemblies move in unison while unmated from the respective connectors in a side plane of the rack. The method may further comprise rotating the shaft in a second rotational direction opposite the first rotational direction to unmate the one or more electrical connectors of each of the subassemblies from the corresponding mating connectors of the rack.

In a fifth example, a tray may comprise electronic components and a plurality of subassemblies along two opposite sides of the tray. In some embodiments, each assembly may comprise a plurality of subassemblies, and each subassembly may comprise one or more support members configured to respectively receive one or more electrical connectors. Each subassembly may also comprise a subassembly actuator configured to drive the one or more support members of the subassembly relative to the one or more support members of the other subassemblies.

Optionally, each of the assemblies may further comprise an actuator configured to drive the subassemblies in unison. The actuator may be a first actuator, and the assembly may further comprise a second actuator separated from the first actuator by the subassemblies. The first and second actuators may respectively include a first eccentric element and a second eccentric element with a same shape as the first eccentric element. The first and second eccentric elements may be configured to drive the subassemblies when rotated. Each of the subassemblies may move a same distance in unison during a first phase based on the first and/or second actuators, and the subassemblies may move sequentially during a second phase based on the subassembly actuator. In some embodiments, an amount of the same distance may be based on a height of a slot accommodating the assembly. In some embodiments, an amount of the same distance may be at least 1 millimeter (mm) per 5 mm height of the slot and the same distance may be greater than 10 mm.

Optionally, the subassembly actuator of each of the subassemblies is a first subassembly actuator and the subassembly further comprises a second subassembly actuator separated from the first subassembly actuator by the one or more support members. The first and second subassembly actuators may respectively include a first subassembly eccentric element and a second subassembly eccentric element with a same shape as the first subassembly eccentric element. The first and second subassembly eccentric elements may be configured to drive the one or more support members when rotated.

Optionally, each of the subassemblies may include at least two support members configured to respectively receive at least two electrical connectors. The at least two support members may be configured to be driven in unison by the subassembly actuator. In some embodiments, the at least two electrical connectors are in a stacked arrangement. In some embodiments, the at least two electrical connectors are in a side-by-side arrangement.

Optionally, the subassemblies may be driven sequentially based on sequential actuation by the subassembly actuator of each of the subassemblies.

Optionally, the assembly may be disposed on a tray and the one or more electrical connectors of each of the subassemblies may be mated to a corresponding mating connector in a rack into which the tray may be inserted.

In a sixth example, a connector actuator component is provided. The connector actuator component may comprise a plurality of connector subassemblies, and each subassembly may include one or more support members configured to respectively receive one or more electrical connectors. The connector actuator component may also comprise an actuator configured to drive the connector subassemblies in unison. The connector actuator component may also comprise a shaft extending through the actuator and the connector subassemblies, and the shaft may be configured to rotate based on an interface to an external device.

Optionally, the shaft may extend from a first end wall to a second end wall, and the subassemblies and the actuator may be between the first and second end walls. The connector actuator component may further comprise a keyed element at an end of the shaft, and the keyed element may be configured to interface with an external keyed element of the external device.

The connector actuator component may further comprise a first slot formed in the first end wall and a second slot formed in the second end wall, and the shaft may extend from the first slot to the second slot. The keyed element at the end of the shaft may be separated from the subassemblies and the actuator by the first end wall. The connector actuator component may further comprise one or more guide slots in the first end wall, and the one or more guide slots may be configured to receive respective one or more guide pins extending from the external device.

In a seventh example, a method of mounting a tray in a rack is provided. The method may comprise inserting the tray into the rack. The tray may include a connector actuator component comprising a plurality of connector subassemblies, and each subassembly may include one or more support members configured to respectively receive one or more electrical connectors. The connector actuator component may also comprise an actuator configured to drive the connector subassemblies. The connector actuator component may also comprise a shaft extending through the actuator and the connector subassemblies, and the shaft may be configured to rotate based on an interface to an external device outside the tray. The method may further comprise coupling the connector actuator component to the external device. The method may further comprise rotating the shaft coupled the actuator and the connector subassemblies in a first rotational direction over a first angular distance over which the connector subassemblies move together.

Optionally, the step of coupling the connector actuator component to the external device may comprise interfacing a keyed element at a first end of the shaft with an external keyed element extending from the external shaft of the external device.

Optionally, the step of coupling the connector actuator component to the external device comprises respectively receiving, into one or more guide slots in an end wall of a drive mechanism, one or more guide pins extending from the external device.

In an eighth example, a drive mechanism is provided. The drive mechanism may comprise: a housing having a first side and a second side; at least one shaft; an engagement feature on a first end of a shaft of the at least one shaft that extends from the first side of the housing; a keyed element on a second end of a shaft of the at least one shaft that extends from the second side of the housing; and a set of gears coupling the first end of the shaft to the second end of the shaft. In some embodiments, the keyed element may be configured to receive a keyed element having a surface contour different than the engagement feature.

Optionally, the drive mechanism may further comprise one or more guide pins protruding at the second side of the housing. In some embodiments, a gear ratio of the gears engaged with the shaft controls an amount of torque needed to rotate the shaft of the drive mechanism via rotation of the engagement feature.

Optionally, the drive mechanism may be configured to be arranged external to a tray in a rack on which the drive mechanism is disposed.

For purposes of this patent application and any patent issuing thereon, the indefinite articles “a” and “an,” as used herein in the specification and in the claims, unless clearly indicated to the contrary, should be understood to mean “at least one.” The phrase “and/or” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

The use of “including,” “comprising,” “having,” “containing,” “involving,” and/or variations thereof herein, is meant to encompass the items listed thereafter and equivalents thereof as well as additional items.

It should also be understood that, unless clearly indicated to the contrary, in any methods claimed herein that include more than one step or act, the order of the steps or acts of the method is not necessarily limited to the order in which the steps or acts of the method are recited.

What is claimed is:

1. An assembly comprising:
a plurality of subassemblies, each subassembly of the plurality of subassemblies comprising:
one or more support members configured to respectively receive one or more electrical connectors; and
a subassembly actuator configured to drive the one or more support members of the subassembly relative to the one or more support members of other subassemblies of the plurality of subassemblies.

2. The assembly of claim 1, further comprising an assembly actuator configured to drive the plurality of subassemblies in unison.

3. The assembly of claim 2, wherein:
the assembly actuator is a first assembly actuator;
the assembly further comprises a second assembly actuator; and
the plurality of subassemblies are between the first assembly actuator and the second assembly actuator.

4. The assembly of claim 3, wherein each of the first assembly actuator and the second assembly actuator includes a bidirectional camming element comprising a first eccentric element and a second eccentric element, with a same shape as the first eccentric element, configured to drive the plurality of subassemblies when rotated.

5. The assembly of claim 3, wherein:
the first assembly actuator and the second assembly actuator are configured to move each of the plurality of subassemblies a same distance in unison during a first phase and,
the subassembly actuator of each of the plurality of subassemblies is configured to move a respective subassembly during a second phase such that the plurality of subassemblies move sequentially during the second phase.

6. The assembly of claim 5, wherein an amount of the same distance is based on a height of a slot accommodating the assembly.

7. The assembly of claim 5, wherein an amount of the same distance is at least 1 millimeter (mm) per 5 mm height of a slot accommodating the assembly and the same distance is greater than 10 mm.

8. The assembly of claim 1, wherein each of the plurality of subassemblies:
the subassembly actuator is a first subassembly actuator;
the subassembly further comprises a second subassembly actuator; and
the one or more support members is between the first subassembly actuator and the second subassembly actuator.

9. The assembly of claim 8, wherein the first subassembly actuator and the second subassembly actuator respectively include a camming element configured to drive the one or more support members when rotated.

10. The assembly of claim 1, wherein the support member of each subassembly of the plurality of subassemblies is configured to support at least two electrical connectors.

11. The assembly of claim 10, wherein the at least two electrical connectors of each subassembly are in a stacked arrangement.

12. The assembly of claim 10, wherein the at least two electrical connectors of each subassembly are in a side-by-side arrangement.

13. The assembly of claim 1, wherein the plurality of subassemblies are driven sequentially based on sequential actuation by the subassembly actuators of each of the plurality of subassemblies.

14. The assembly of claim 1, wherein the assembly is disposed on a tray and the one or more electrical connectors of each of the plurality of subassemblies is mated to a corresponding mating connector in a rack into which the tray is inserted.

15. An assembly comprising:
a plurality of subassemblies, each subassembly of the plurality of subassemblies including one or more support members configured to respectively receive one or more electrical connectors; and
an actuator configured to drive the plurality of subassemblies in unison.

16. The assembly of claim 15, wherein:
the actuator comprises a first actuator;
the assembly further comprises a second actuator; and
the plurality of subassemblies are between the first actuator and the second actuator.

17. The assembly of claim 16, wherein the first actuator and the second actuator respectively include a first eccentric element and a second eccentric element, with a same shape as the first eccentric element, configured to drive the plurality of subassemblies when rotated.

18. The assembly of claim 16, wherein, the first actuator and the second actuator are coupled to the plurality of subassemblies such that each of the plurality of subassemblies move a same distance in unison during a first phase.

19. The assembly of claim 15, wherein each subassembly of the plurality of subassemblies includes a subassembly actuator configured to drive the one or more support members of the subassembly relative to the one or more support members of other subassemblies of the plurality of subassemblies.

20. A method of mounting a tray in a rack, the method comprising:
inserting the tray into the rack, wherein the tray includes an assembly comprising:
a plurality of subassemblies, each subassembly of the plurality of subassemblies including one or more support members configured to respectively receive one or more electrical connectors, and
an actuator configured to drive the plurality of subassemblies; and
rotating a shaft coupled to the actuator and the plurality of subassemblies in a first rotational direction over a first angular distance over which the plurality of subassemblies move together.

21. The method of claim 20, further comprising rotating the shaft in the first rotational direction over a second angular distance over which the plurality of subassemblies move sequentially.

22. The method of claim 21, further comprising:
mating the one or more electrical connectors of each of the plurality of subassembly with corresponding connectors of the rack while rotating the shaft over the second angular distance.

23. The method of claim 22, further comprising:
rotating the shaft in a second rotational direction, opposite the first rotational direction, to unmate the one or more electrical connectors of each of the plurality of subassemblies from the corresponding mating connectors of the rack.

24. A drive mechanism, comprising:
a housing comprising a first side and a second side;
at least one shaft;
an engagement feature on a first end of a shaft of a shaft of the at least one shaft and extending from the first side of the housing;
a keyed element on a second end of a shaft of the at least one shaft and extending from the second side of the housing; and
a set of gears coupling the first end of a shaft to the second end of the shaft,
wherein the keyed element is configured to receive a keyed element having a surface contour different than the engagement feature.

25. The drive mechanism of claim 24, further comprising one or more guide pins protruding at the second side of the housing.

26. The drive mechanism of claim 25, wherein a gear ratio of the gears engaged with the shaft controls an amount of torque needed to rotate the shaft of the drive mechanism via rotation of the engagement feature.

27. The drive mechanism of claim 24, wherein the drive mechanism is configured to be arranged external to a tray in a rack on which the drive mechanism is disposed.
